(19) United States
(12) Patent Application Publication
(10) Pub. No.: US 2006/0098414 A1
(43) Pub. Date: May 11, 2006

(54) Heat sink

(76) Inventor: Meng-Cheng Huang, Taipei (TW)

Correspondence Address: HDSL, 4331 STEVENS BATTLE LANE, FAIRFAX, VA, 22033, US

(21) Appl. No.: 10/984,452

(22) Filed: Nov. 10, 2004

(51) Int. Cl. H05K 7/20

(52) U.S. Cl. 361/709; 165/104.33

(57) ABSTRACT

A heat sink is heat sinkdisposed facing the air output of a fan. A concave portion is formed on the heat sink facing the fan. The air flow generated from the fan encounters the concave portion of the heat sink. The concave portion can evenly distribute the air speed flowing from the fan to enhance the cooling effect.

### BACKGROUND OF THE INVENTION

The present invention relates generally to a heat sink, and more particularly to a heat sink that can evenly distribute the air speed flowing from a fan to enhance the fin cooling effect, thereby achieving a better cooling effect.

A conventional heat sink 5 as shown in FIG. 1, includes a plurality of fins 51, while one or more passages 52 are formed between the fins 51. A fan 6 can be disposed at one side of the heat sink 5 corresponding to the passages 52 of the heat sink 5, and a heat conduit 7 is disposed at the bottom portion of the heat sink 5. The heat conduit 7 is connected to a heat conducting plate 8 that can be disposed on a central processing unit. In this manner, the heat conducting plate 8 can absorb heat generated from the central processing unit and conduct the heat to the heat sink 5. The fan 6 then blows air through the air output 61 and guides the air into the passages 52 of the heat sink 5. The air is thus evacuated from the passages 52 of the fins 51, meanwhile bringing the heat on the heat sink 5 away with the air and achieving the cooling effect.

The aforementioned heat sink 5 can achieve certain cooling effect. However, since the fan 6 is of a radial style, the central portion of the heat sink 5 encounters weaker air flow while the two sides of the heat sink 5 encounters stronger air flow. For this reason, the central portion of the heat sink 5 can accumulate heat, such that the heat can not be dissipated evenly. Therefore, the development of a new heat sink is needed.

### BRIEF SUMMARY OF THE INVENTION

The present invention is to provide a heat sink that can solve the drawbacks as set forth above. The heat sink of the present invention can evenly distribute the air speed flowing from a fan to enhance the cooling effect.

In order to achieve the above and other purposes, the heat sink of the present invention is disposed facing the air output of a fan. A concave portion is formed on the heat sink facing the fan. The air flow generated from the fan encounters the concave portion of the heat sink. The concave portion can evenly distribute the air speed flowing from the fan to enhance the cooling effect.

### BRIEF DESCRIPTION OF THE DRAWINGS

FIG. 1 illustrates a conventional heat sink in use.

FIG. 2 is a perspective view of a heat sink, in accordance with the first embodiment of the present invention.

FIG. 3 is a top view of a heat sink, in accordance with the first embodiment of the present invention.

FIG. 4 is a perspective view of a heat sink in assembly with a fan, in accordance with the first embodiment of the present invention.

FIG. 5 illustrates the heat sink in use, in accordance with the first embodiment of the present invention.

FIG. 6 illustrates the heat sink, in accordance with the second embodiment of the present invention.

FIG. 7 illustrates the heat sink, in accordance with the third embodiment of the present invention.

FIG. 8 illustrates the heat sink, in accordance with the fourth embodiment of the present invention.

FIG. 9 illustrates the heat sink, in accordance with the fifth embodiment of the present invention.

FIG. 10 illustrates the heat sink, in accordance with the sixth embodiment of the present invention.

FIG. 11 is a top view of the heat sink, in accordance with the sixth embodiment of the present invention.

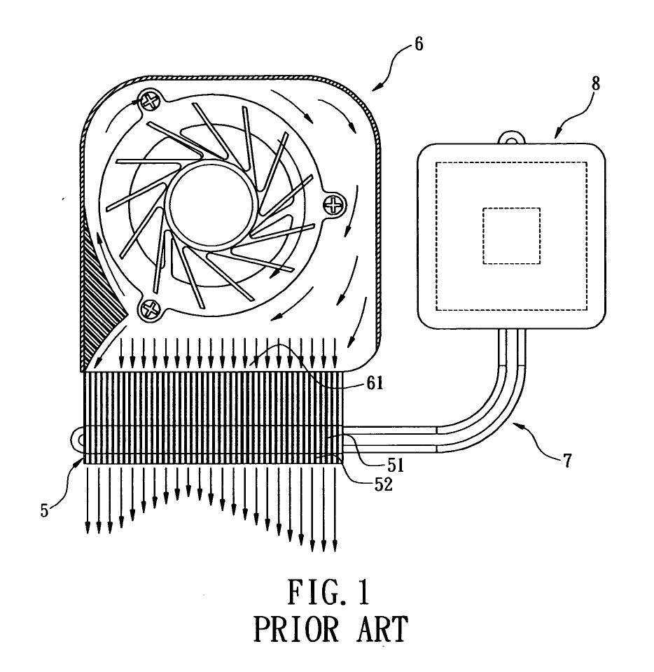

### DETAILED DESCRIPTION OF THE INVENTION

In order to better understanding the features and technical contents of the present invention, the present invention is hereinafter described in detail by incorporating with the accompanied drawings. However, the accompanied drawings are only for the convenience of illustration and description, no limitation is intended thereto.

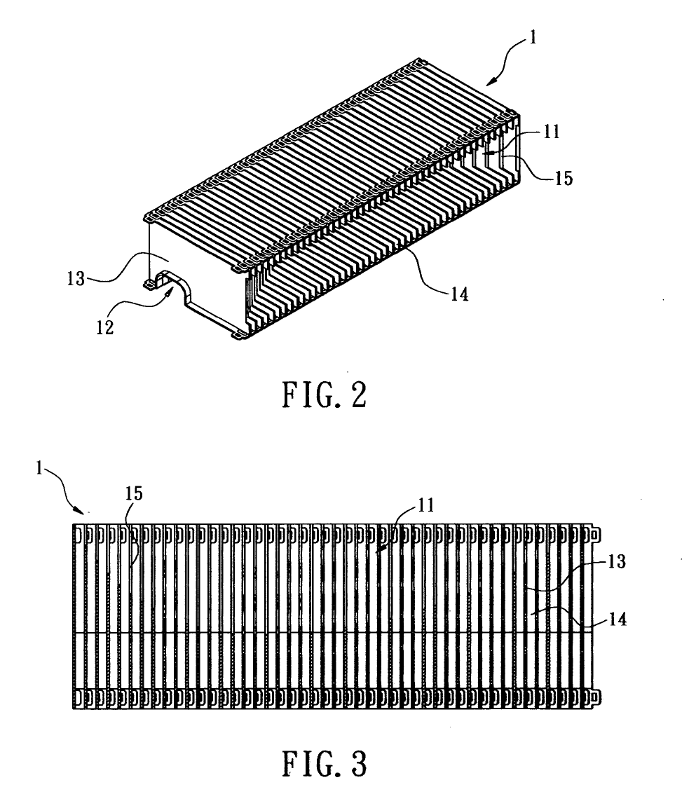

Referring to FIG. 2 and FIG. 3, a perspective view and a top view of a heat sink in accordance with the first embodiment of the present invention are illustrated. As shown, the heat sink 1 is configured to dispose on the air output of a fan (not shown). The heat sink 1 can evenly distribute the air speed flowing from the fan to enhance the cooling effect.

The heat sink 1 has an inwardly formed concave portion 11 that corresponds to the air output of the fan (not shown). The bottom of the heat sink includes an assembly portion 12. The heat sink 1 is composed of one or more fins 13. A passage 14 is formed between each two adjacent fins 13. One end of each fin 13 has a notch 15 formed thereon (the closer to the central portion of the heat sink 1, the deeper of the notch 15 formed on the fin 13.) By employing the notches 15 of different depth, the concave portion 11 having an arch shape is thus formed. In this manner, a new heat sink is developed.

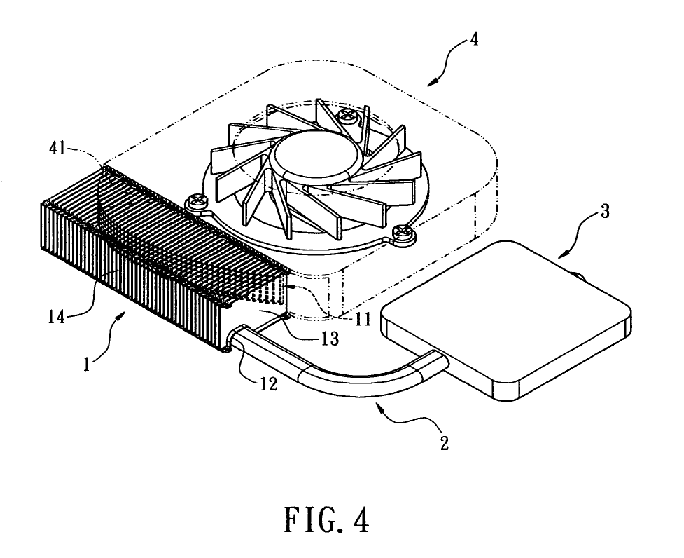

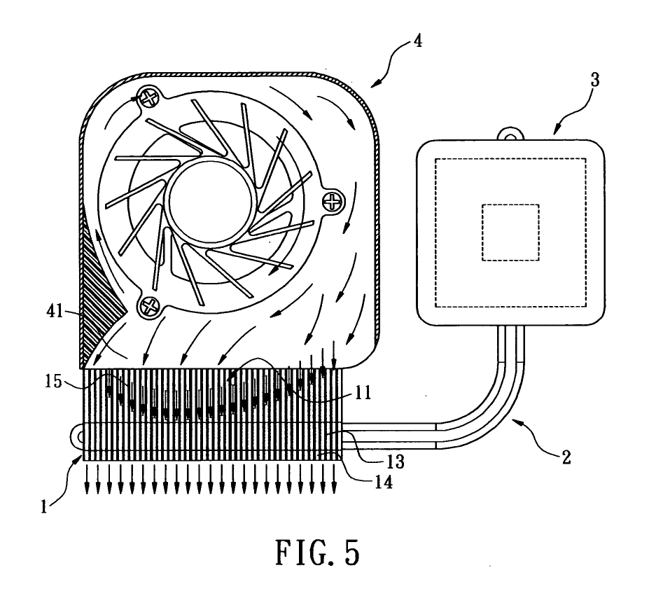

Referring to FIG. 4 and FIG. 5, the heat sink in assembly and in use are illustrated, in accordance with the first embodiment of the present invention. As shown, a heat pipe 2 can be assembled to the assembly portion 12 of the heat sink 1. A heat conducting plate 3 can be connected to one end of the heat pipe 2. When using the heat sink of the present invention, one can place the heat conducting plate 3 on a heat generating element (e.g. a CPU or other parts) of a motherboard. The concave portion 11 of the heat sink 1 is disposed facing the air output 41 at one side of the fan 4.

When the heat generating element is running, there is generated a heat source. The heat conducting plate 3 absorbs the heat generated from the heat generating element. The fan 4 blows air through the air output 41 to the concave portion 11 of the heat sink. The concave portion 11 can evenly distribute the air speed blown from the fan. Thus, the fins 13 can have better cooling effects.

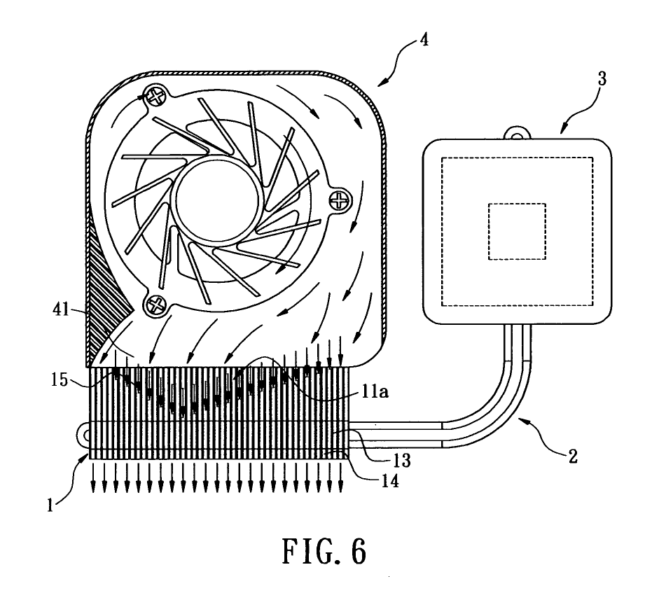

Referring to FIG. 6, the second embodiment of the present invention is illustrated. As shown, in addition to an arch shape as set forth above, the concave portion 11 can also be of a gradually indenting shape. Such a configuration can also make the air speed being evenly distributed from the fan 4, as described above. The cooling effect of the fins 13 is thus enhanced.

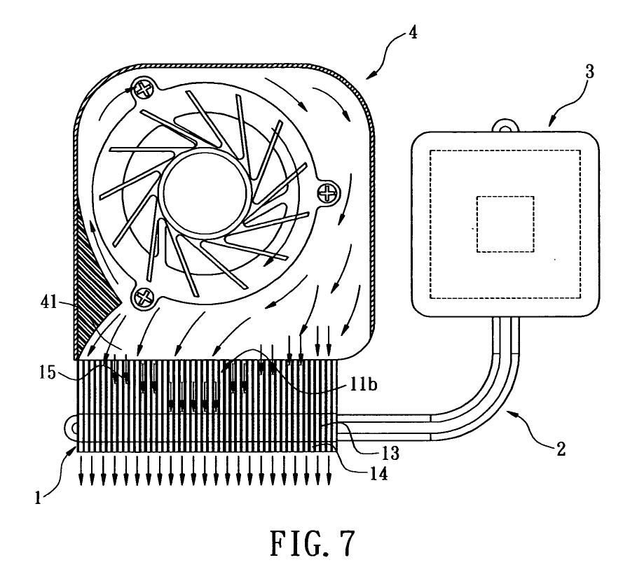

Referring to FIG. 7, the third embodiment of the present invention is illustrated. As shown, in addition to an arch shape as set forth above, the concave portion 11 can also be of a step shape. Such a configuration can also make the air speed being evenly distributed from the fan 4, as described above. The cooling effect of the fins 13 is thus enhanced.

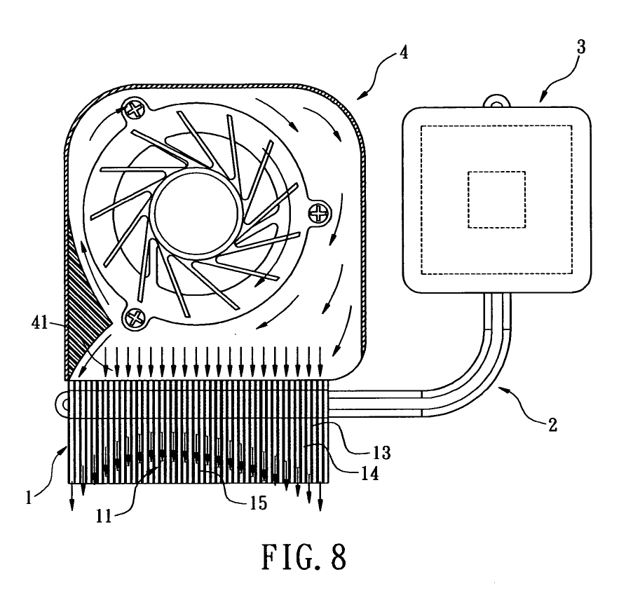

Referring to FIG. 8, the fourth embodiment of the present invention is illustrated. As shown, the assembly configuration shown in FIG. 8 is substantially the same as that shown in FIG. 4. However, the difference between FIG. 8 and FIG. 4 is in that the concave portion 11 of the heat sink 1 is counter facing the air output 41 of the fan 4. Such a configuration can still evenly distribute the air flow from the fan 4, so as to enhance the cooling effect of the fins 13.

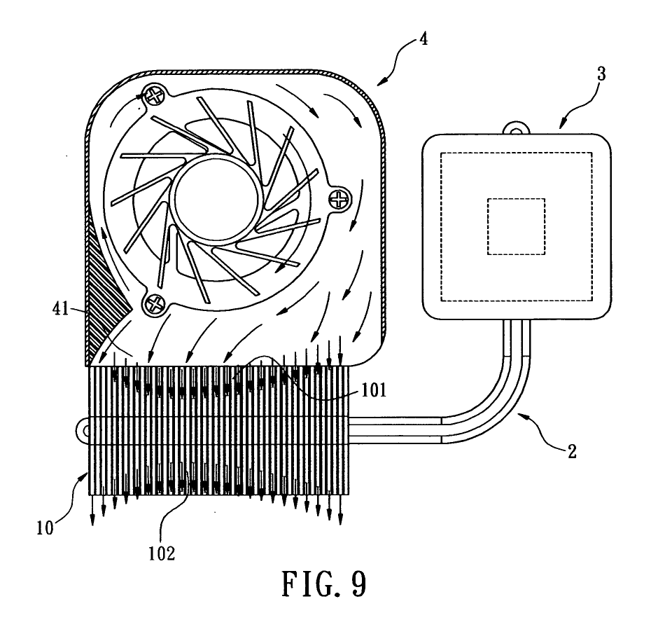

Referring to FIG. 9, the fifth embodiment of the present invention is illustrated. As shown, the concave portion 101 of the heat sink 10 is the same as the concave portion 11 of the heat sink 11 shown in FIG. 2. However, the difference between the concave portions 1 and 10 is in that the heat sink 10 includes another concave portion 102. The two concave portions 101, 102 can be of the same shape or of different shapes. The air speed from the fan 4 can also be evenly distributed, thereby enhancing the cooling effect of the fins 13.

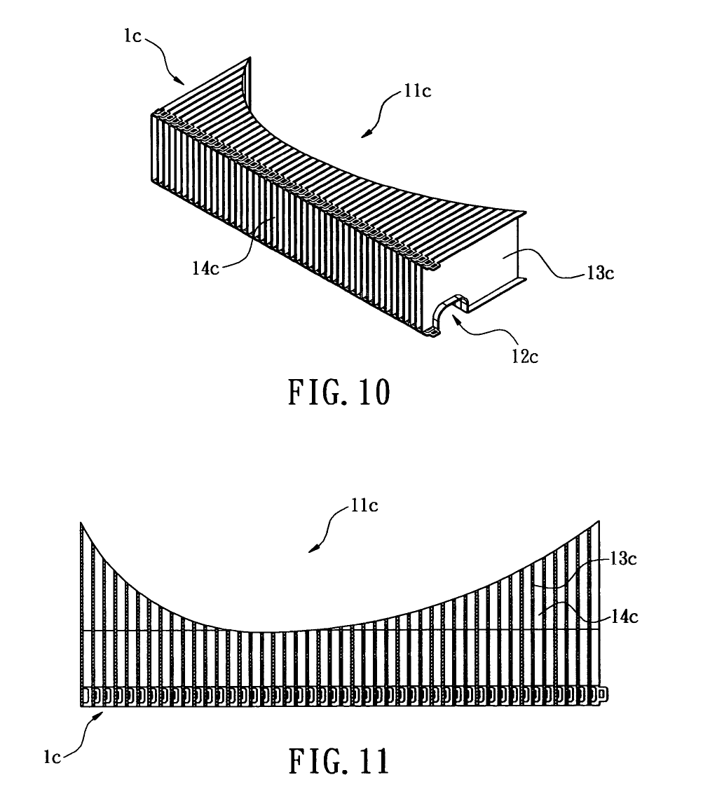

Referring to FIGS. 10 and 11, the perspective view and the top view of the sixth embodiment of the present invention are illustrated. As shown, there is formed a concave portion 11c on the heat sink 1c facing the air output of a fan (not shown). The bottom portion of the heat sink 1c includes a assembly portion 12c. The heat sink 1 is composed of one or more fins 13c. A passage 14c is formed between each adjacent two fins 13c. The lengths of fins 13c are different from each other (the closer to the central portion of the heat sink 1c, the shorter the length of the fin 13c.) Therefore, a concave portion 11c can be formed on the heat sink 1.

Since, any person having ordinary skill in the art may readily find various equivalent alterations or modifications in light of the features as disclosed above, it is appreciated that the scope of the present invention is defined in the following claims. Therefore, all such equivalent alterations or modifications without departing from the subject matter as set forth in the following claims is considered within the spirit and scope of the present invention.

1. A heat sink for distributing air flow from a fan, the heat sink comprising a concave portion, whereby the concave portion can evenly distribute the air flow speed from the fan to enhance the cooling effect.

2. The heat sink as recited in claim 1, wherein the concave portion is one of an arch shape, a gradually indenting shape, and a step shape.

3. The heat sink as recited in claim 1, wherein the heat sink comprises one or more fins, wherein a passage is formed between each adjacent two fins, one end of each fin having a notch of a different depth, thereby forming the concave portion.

4. The heat sink as recited in claim 1, wherein the concave portion is facing or counter facing the air output of the fan.

5. The heat sink as recited in claim 1, wherein the bottom portion of the heat sink comprises an assembly portion for assembling thereon a heat pipe, one end of the heat pipe connecting a heat conducting plate.

6. A heat sink for distributing air flow from a fan, the heat sink comprising a concave portion formed on one end of the heat sink, whereby the concave portion can evenly distribute the air flow speed from the fan to enhance the cooling effect.

7. The heat sink as recited in claim 6, wherein the heat sink comprises one or more fins, wherein a passage is formed between each adjacent two fins, thereby forming a concave portion.

8. A heat sink for distributing air flow from a fan, the heat sink comprising two concave portions formed on two opposite ends of the heat sink, whereby the concave portions can evenly distribute the air flow speed from the fan to enhance the cooling effect.

9. The heat sink as recited in claim 8, wherein the two concave portions are of the same or of different shapes.

10. (canceled)
